(19) United States
(12) Patent Application Publication
(10) Pub. No.: US 2014/0301035 A1
(43) Pub. Date: Oct. 9, 2014

(54) AIR SHIELD FOR RACK-MOUNT SERVER

(71) Applicants: Hon Hai Precision Industry Co., Ltd., New Taipei (TW); Hong Fu Jin Precision Industry (ShenZhen) Co., Ltd., Shenzhen (CN)

(72) Inventor: LI-FANG FAN, Shenzhen (CN)

(73) Assignees: HON HAI PRECISION INDUSTRY CO., LTD., New Taipei (TW); HONG FU JIN PRECISION INDUSTRY (ShenZhen) CO., LTD., Shenzhen (CN)

(21) Appl. No.: 13/873,163

(22) Filed: Apr. 29, 2013

(30) Foreign Application Priority Data
Apr. 9, 2013 (CN) 2013101215434

(51) Int. Cl. H05K 7/20

(52) U.S. Cl. CPC H05K 7/20709; H05K 7/20009
USPC 361/679.46; 454/184

(57) ABSTRACT

An air shield is mounted to a cabinet to replace a server unit. The air shield includes a supporting shell detachably mounted in an opening defined the cabinet through which the server unit can enter the receiving space, and an adjusting apparatus slidably installed to the supporting shell. The supporting shell defines a number of vents communicating with the receiving space of the cabinet. The adjusting apparatus includes a number of spaced shield pieces. The adjusting apparatus is operated, to move the shield pieces to cover, partially cover, or uncover the vents of the supporting shell.

### BACKGROUND

1. Technical Field

The present disclosure relates to an air shield for shielding a rack-mount server.

2. Description of Related Art

A rack-mount server can be used to receive different types of server units. Dummy server models are often used to replace the server units for testing the airflow resistance of the rack-mount server. However, the dummy server models are integrally formed, and cannot be adjusted, so it is inconvenient to replace the different types of server units.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, all the views are schematic, and like reference numerals designate corresponding parts throughout the several views.

FIG. 1 is an isometric, exploded view of an exemplary embodiment of a rack-mount server, wherein the rack-mount server includes a plurality of air shields.

FIG. 2 is an exploded, enlarged, isometric view of one of the air shields of FIG. 1.

FIG. 3 is similar to FIG. 2, but viewed from another perspective.

FIG. 4 is an assembled, isometric view of the air shield of FIG. 2.

FIG. 5 is an assembled, isometric view of FIG. 1.

FIG. 6 is a sectional view of FIG. 4, taken along the line of VI-VI.

FIG. 7 is similar to FIG. 6, but shows a different state of use.

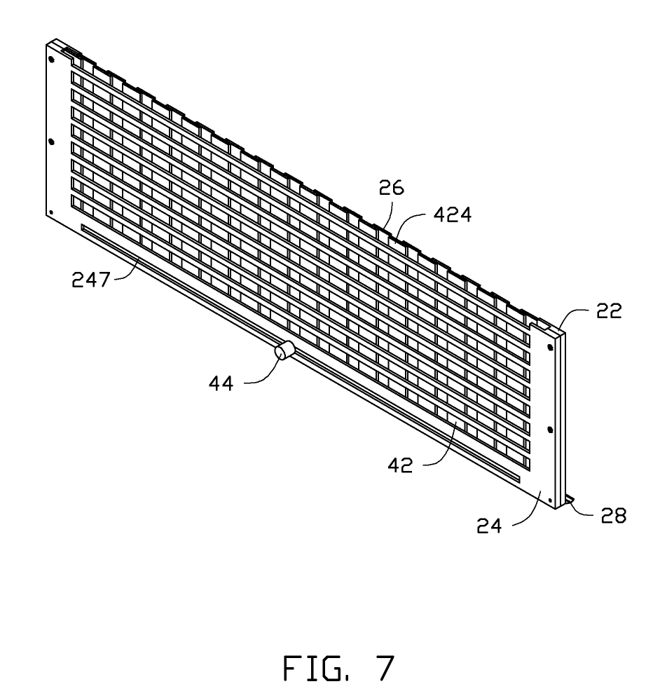

### DETAILED DESCRIPTION

The disclosure, including the accompanying drawings, is illustrated by way of examples and not by way of limitation. It should be noted that references to “an” or “one” embodiment in this disclosure are not necessarily to the same embodiment, and such references mean at least one.

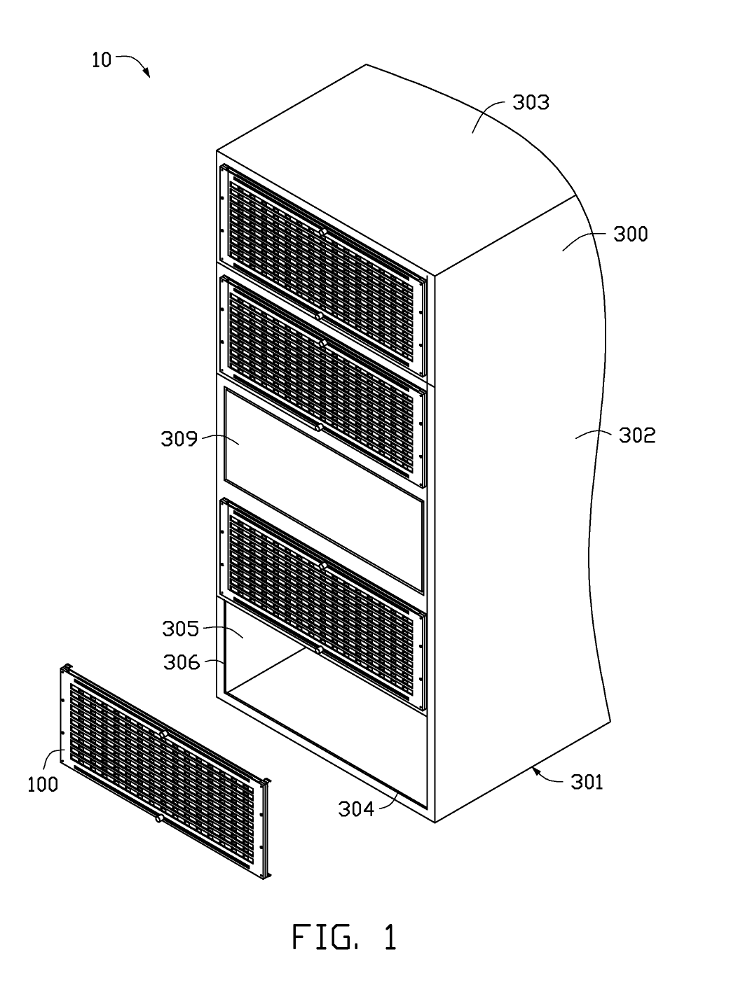

FIG. 1 shows an exemplary embodiment of a rack-mount server 10. The rack-mount server 10 includes a cabinet 300 and a plurality of air shields 100. Each air shield 100 can be mounted to the cabinet 300.

The cabinet 300 includes a bottom wall 301, two sidewalls 302 perpendicularly extending up from two opposite sides of the bottom wall 301, and a top wall 303 perpendicularly connected between tops of the sidewalls 302. A plurality of spaced latching bars 304 are arranged from top to bottom and are perpendicularly connected between front sides of the sidewalls 302. The bottom wall 301, the sidewalls 302, and the top wall 303 cooperatively bound a receiving space 305, for receiving a plurality server units 309. A rectangular opening 306 is defined between every two adjacent latching bars 304, through which a server unit 309 enters the receiving space 305.

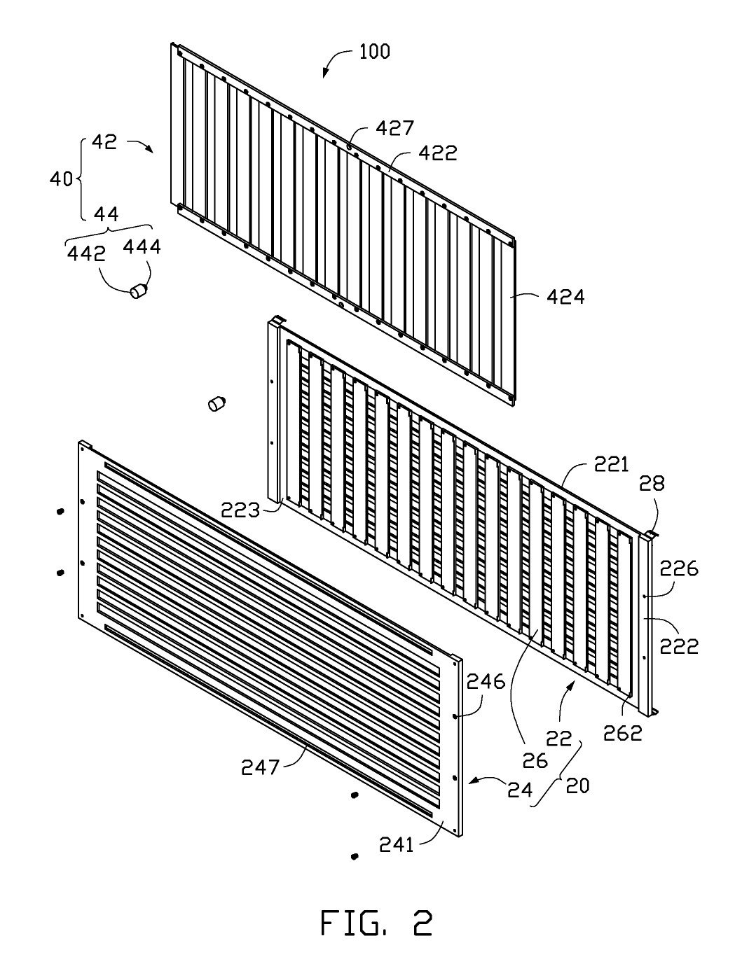

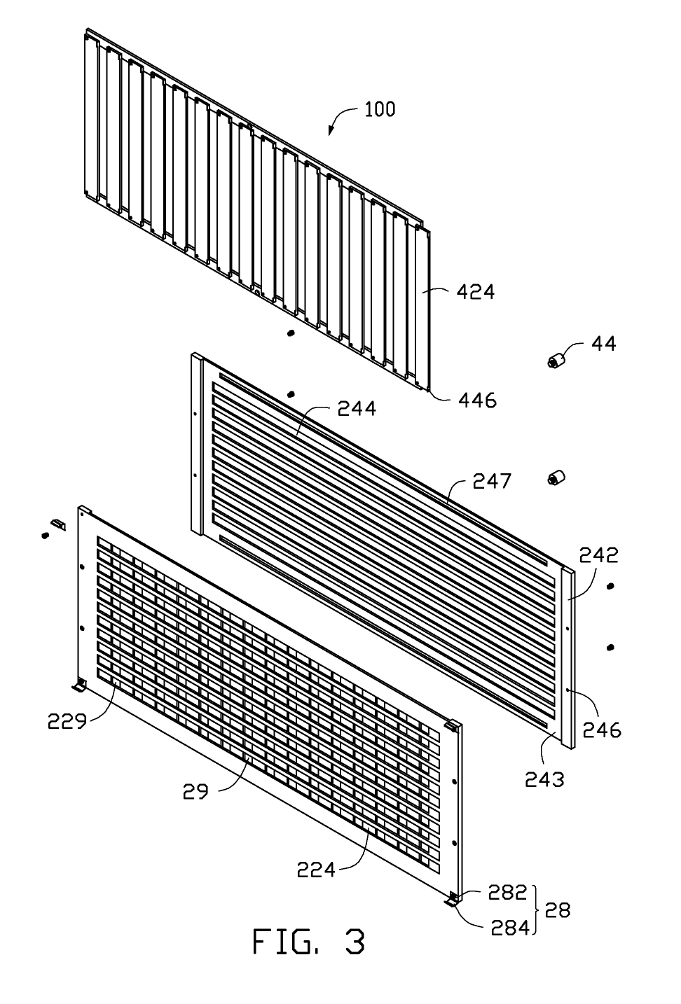

FIGS. 2 and 3 show one of the air shields 100. The air shield 100 includes a supporting shell 20 and an adjusting apparatus 40.

The supporting shell 20 includes a supporting member 22, a cover 24, a plurality of partition plates 26 mounted to the supporting plate 22, and four latching members 28. The supporting member 22 includes a rectangular rear plate 221 and two first flanges 222 protruding forward from two opposite ends of the rear plate 221. The rear plate 221 and the first flanges 222 cooperatively bound a rectangular first space 223. The rear plate 221 defines a plurality of parallel first ventilation slots 224 between the first flanges 222. Each first ventilation slot 224 extends perpendicular to the first flanges 222, along a lengthwise direction of the rear plate 221, and communicates with the first space 223. The partition plates 26 are received in the first space 223, and mounted to the rear plate 221. The partition plates 26 are perpendicular to the first ventilation slots 224. Therefore, the first ventilation slots 224 are divided into a plurality of vents 29 through the partition plates 26. Each first flange 222 defines two screw holes 226. The latching members 28 are mounted to four corners of the rear plate 221 opposite to the first flanges 222. Two tabs 262 protrude forward from two opposite ends of a side of each partition plate 26 adjacent to one of the first flanges 222.

The cover 24 includes a rectangular front plate 241 and two second flanges 242 protruding rearward from two opposite ends of the front plate 24. The second flanges 242 and the front plate 24 cooperatively bound a second space 243. The front plate 241 defines two slide slots 247 in two opposite sides of the front plate 241, and a plurality of parallel second ventilation slots 244 between the slide slots 247. The second ventilation slots 244 and the slide slots 247 extend perpendicular to the second flanges 242 along a lengthwise direction of the front plate 241. The second ventilation slots 244 and the slide slots 247 communicate with the second space 243. Each second flange 242 defines two through holes 246.

Each latching member 28 includes a mounting piece 282 fixed to the rear plate 221, and a V-shaped resilient latching piece 284 extending rearward from the mounting piece 282.

The adjusting apparatus 40 includes a substantially rectangular sliding member 42 and two operation members 44. The sliding member 42 includes two opposite slide bars 422 and a plurality of spaced shield pieces 424 perpendicularly mounted between the slide bars 422. Two tabs 446 perpendicularly protrude rearward from two opposite ends of a side of each shield piece 424 facing one of opposite ends of the sliding member 42. A middle of each slide bar 422 defines a screw hole 427.

Each operation member 44 includes a cylindrical operation portion 442 and a connecting pole 444 axially protruding out from an end of the operation portion 442. The connecting pole 444 defines external threads.

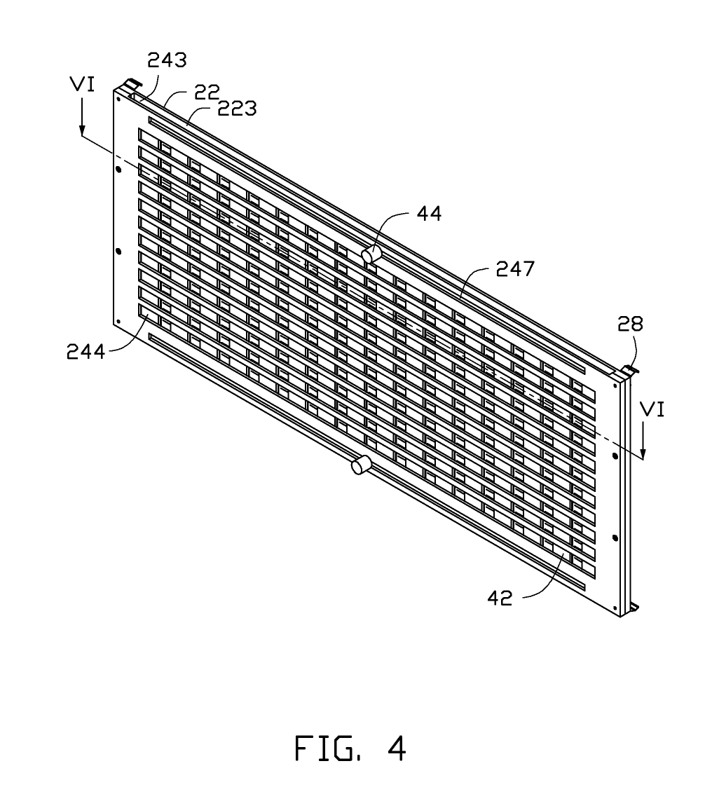

FIG. 4 shows that in assembly of the air shield 100, the sliding member 42 is received in the first space 223 of the supporting member 22, to allow the shield pieces 424 to align with the partition plates 26, respectively. The cover 24 is covering the supporting member 22, allowing the second flanges 242 of the cover 24 to engage with the first flanges 222 of the supporting member 22, with the through holes 246 aligning with the screw holes 226. The first ventilation slots 224 align with the second ventilation slots 244. The sliding member 42 is slidably received in the first and second spaces 223 and 243, and can be stopped by the tabs 262 of the partition plates 26 and the tabs 446 of the corresponding shield pieces 424. The screw holes 427 of the slide bars 422 are respectively aligned with the slide slots 247 of the cover 24. The connecting poles 444 of the operation members 44 extend through the slide slots 247 from a front of the cover 24, to be screwed into the screw holes 427 of the sliding member 42. Four screws extend through the through holes 246 of the cover 24, to be screwed into the screw holes 226 of the supporting member 22.

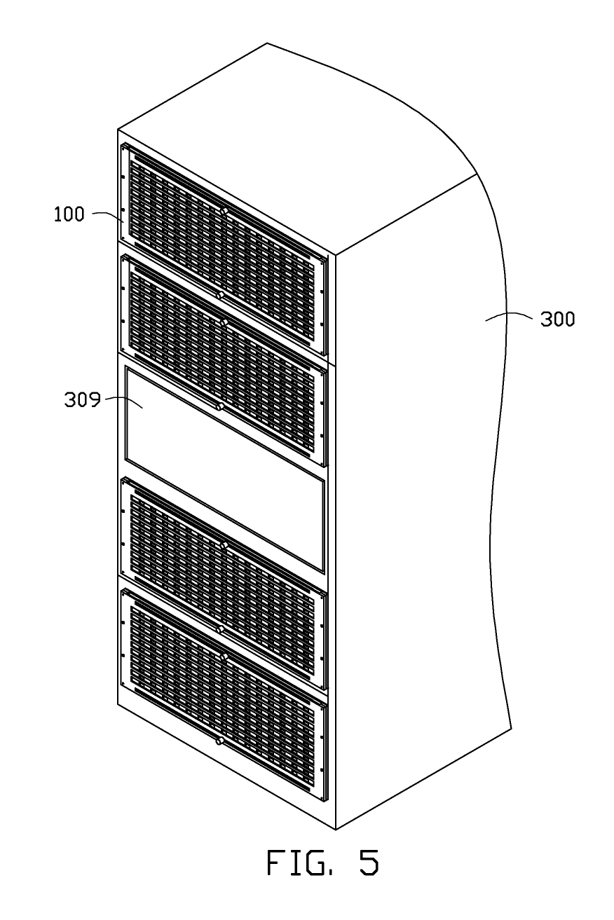

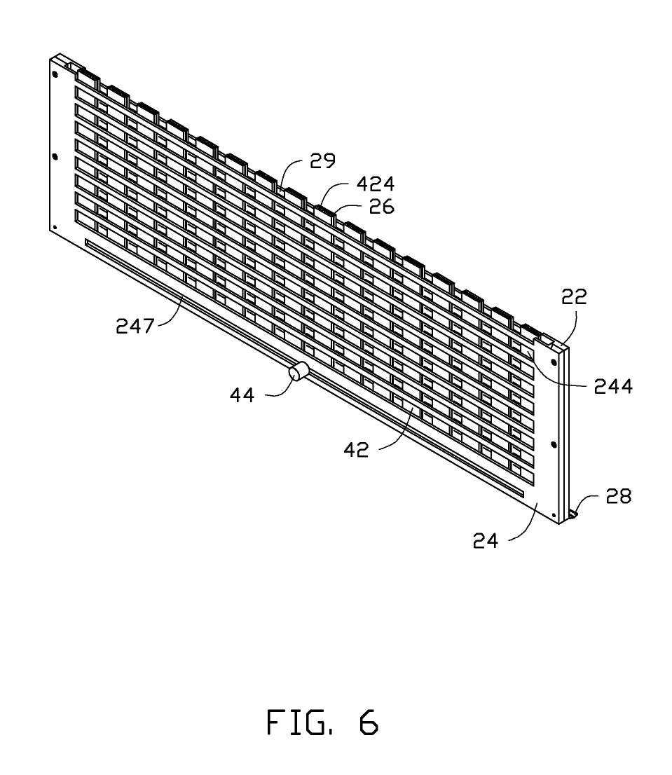

FIGS. 5 and 6 show that in use, each air shield 100 is installed to an opening 306 of the cabinet 300 in which the server unit 309 is not installed. The latching members 28 of each air shield 100 are inserted into the receiving space 305 from the corresponding opening 306. The latching pieces 284 are slidably abutted against the corresponding latching bars 304 of the cabinet 300, deforming the latching pieces 284, until the latching pieces 284 pass through the latching bars 304. The latching pieces 284 are restored to latch with the latching bars 304. Thereby, the air shield 100 is mounted in the opening 306 of the cabinet 300. The operation portions 442 of each air shield 100 is operated, the operation members 44 are slid along the slide slots 247, to allow the sliding member 42 to slide. The shield pieces 424 are slid relative to the corresponding partition plates 26, and the vents 29 are gradually covered or uncovered. Size of the vents 29 can be changed by operating the adjusting apparatus 40 to cover, partially cover, or uncover the vents 29, to simulate different types of server units 309 with different airflow resistance.

It is to be understood, however, that even though numerous characteristics and advantages of the embodiment have been set forth in the foregoing description, together with details of the structure and function of the embodiment, the disclosure is illustrative only, and changes may be made in detail, especially in the matters of shape, size, and arrangement of parts within the principles of the present disclosure to the full extent indicated by the broad general meaning of the terms in which the appended claims are expressed.

What is claimed is:

1. An air shield for being mounted to a cabinet to simulate a server unit with airflow resistance, the air shield comprising:
a supporting shell detachably mounted to an opening defined in the cabinet through which the server unit can enter a receiving space of the cabinet; and
an adjusting apparatus slidably installed in the supporting shell;
wherein the supporting shell defines a plurality of vents communicating with the receiving space of the cabinet, the adjusting apparatus comprises a plurality of spaced shield pieces, the number of the shield pieces is adjustable to cover or uncover one or more of the plurality of vents of the supporting shell.

2. The air shield of claim 1, wherein the supporting shell comprises a supporting member and a cover mounted to the supporting member, the adjusting apparatus is slidably sandwiched between the supporting member and the cover, the plurality of vents is defined in the supporting member.

3. The air shield of claim 2, wherein the supporting member comprises a rectangular rear plate and two first flanges protruding forward from two opposite ends of the rear plate, the rear plate and the first flanges cooperatively bound a first space, the rear plate defines a plurality of parallel first ventilation slots between the first flanges and communicating with the first space, the supporting shell further comprises a plurality of partition plates received in the first space and mounted to the rear plate, the plurality of vents is defined by dividing the plurality of first ventilation slots through the plurality of partition plates.

4. The air shield of claim 3, wherein each first ventilation slot extends along a lengthwise direction of the rear plate perpendicular to the first flanges, each partition plate is perpendicular to the plurality of first ventilation slots.

5. The air shield of claim 3, wherein the cover comprises a rectangular front plate and two second flanges protruding rearward from two opposite ends of the front plate, the second flanges are mounted to the first flanges, the front plate and the second flanges cooperatively bound a second space communicating with the first space, the front plate defines a plurality of second ventilation slots aligning with the plurality of first ventilation slots of the rear plate, the adjusting apparatus is slidably received in the first and second space.

6. The air shield of claim 5, wherein each first flange defines a plurality of screw holes, each second flange defines a plurality of through holes aligning with the screw holes, a plurality of screws extends through the through holes, and is screwed into the plurality of screw holes.

7. The air shield of claim 5, wherein the adjusting apparatus comprises a sliding member slidably received between the supporting member and the cover, and an operation member, the sliding member comprises two opposite slide bars, the shield pieces are mounted between the slide bars.

8. The air shield of claim 7, wherein the front plate defines a slide slot extending along the lengthwise direction of the front plate, one of the slide bar defines a screw hole aligning with the slide slot, the operation member extends through the slide slot, and is fixed in the screw hole of the slide bar, the operation member is slid along the slide slot.

9. The air shield of claim 8, wherein the operation member comprises an operation portion and a connecting pole protruding out from the operation portion, the connecting pole defines external threads, the connecting pole extends through the slide slot, and is screwed in the screw hole of the sliding member.

10. The air shield of claim 3, wherein the supporting shell further comprises four latching members mounted to four corners of the rear plate opposite to the first flanges, the latching members are detachably latched to the cabinet.

11. The air shield of claim 10, wherein each latching member comprises a mounting piece mounted to the rear plate and a V-shaped resilient latching piece extending rearward from the mounting piece.

12. A rack-mount server, comprising:
a cabinet defining a receiving space, and a plurality of openings communicating with the receiving space;
a plurality of server units received in the receiving space of the cabinet through the corresponding openings; and
an air shield mounted to the cabinet at one of the plurality of openings, wherein the receiving space corresponding to the opening is idle without mounting a corresponding server unit;
wherein the air shield comprises a supporting shell detachably mounted in the opening, and an adjusting apparatus slidably installed to the supporting shell, the supporting shell defines a plurality of vents communicating with the receiving space of the cabinet, the adjusting apparatus comprises a plurality of spaced shield pieces for covering, partially covering, or uncovering the plurality of vents of the supporting shell.

13. The rack-mount server of claim 12, wherein the supporting shell comprises a supporting member and a cover mounted to the supporting member, the adjusting apparatus is slidably sandwiched between the supporting member and the cover, the plurality of vents is defined in the supporting member.

14. The rack-mount server of claim 13, wherein the supporting member comprises a rectangular rear plate and two first flanges protruding forward from two opposite ends of the rear plate, the rear plate and the first flanges cooperatively bound a first space, the rear plate defines a plurality of parallel first ventilation slots between the first flanges and communicating with the first space, the supporting shell further comprises a plurality of partition plates received in the first space and mounted to the rear plate, the plurality vents is defined by dividing the plurality of first ventilation slots through the plurality of partition plates.

15. The rack-mount server of claim 14, wherein each first ventilation slot extends along a lengthwise direction of the rear plate perpendicular to the first flanges, each partition plate is perpendicular to the plurality of first ventilation slots.

16. The rack-mount server of claim 15, wherein the adjusting apparatus comprises a sliding member slidably installed between the supporting member and the cover, the sliding member comprises two opposite slide bars, the shield pieces are mounted between the slide bars.

17. The rack-mount server of claim 16, wherein the adjusting apparatus further comprises an operation member, the front plate defines a slide slot extending along the lengthwise direction of the front plate, one of the slide bar defines a screw hole aligning with the slide slot, the operation member extends through the slide slot, and is fixed in the screw hole of the slide bar, the operation member is slid along the slide slot.

18. The rack-mount server of claim 17, wherein the operation member comprises an operation portion and a connecting pole protruding out from the operation portion, the connecting pole defines external threads, the connecting pole extends through the slide slot, and is screwed in the screw hole of the sliding member.

19. The rack-mount server of claim 14, wherein the cover comprises a rectangular front plate and two second flanges protruding rearward from two opposite ends of the front plate, the second flanges are mounted to the first flanges, the front plate and the second flanges cooperatively bound a second space communicating with the first pace, the front plate defines a plurality of second ventilation slots aligning with the plurality of first ventilation slots of the rear plate, the adjusting apparatus is slidably received in the first and second space.

20. The rack-mount server of claim 14, wherein the supporting shell further comprises four latching members mounted to four corners of the rear plate opposite to the first flanges, the latching members are detachably latched to the cabinet.
